(19) United States
(12) Patent Application Publication
(10) Pub. No.: US 2025/0266312 A1
(43) Pub. Date: Aug. 21, 2025

(54) POWER SEMICONDUCTOR ASSEMBLY HAVING AN EMBEDDED POWER SEMICONDUCTOR DIE AND METHOD FOR FABRICATING THE SAME

(71) Applicant: Infineon Technologies AG, Neubiberg (DE)

(72) Inventors: Andreas Grassmann, Sinzing (DE); Achim Althaus, Regensburg (DE)

(21) Appl. No.: 19/044,106

(22) Filed: Feb. 3, 2025

(30) Foreign Application Priority Data
Feb. 21, 2024 (DE) 102024201588.1

(51) Int. Cl. H01L 23/31; H01L 23/00; H01L 23/373; H01L 25/07; H05K 1/18; H05K 3/00

(52) U.S. Cl. CPC H01L 23/3121; H01L 23/3735; H01L 24/08; H01L 25/072; H05K 1/185; H05K 3/0058; H01L 2224/08225; H01L 2224/08245; H01L 2924/15153; H05K 2201/0129; H05K 2201/10166; H05K 2201/10522; H05K 2203/061

(57) ABSTRACT

A power semiconductor assembly includes: a power semiconductor die having opposing first and second sides; a metal substrate having opposing first and second sides, the first side having a recess in which the power semiconductor die is arranged such that the second side of the power semiconductor die faces a bottom side of the recess; a printed circuit board (PCB) having opposing first and second sides, the power semiconductor die and metal substrate being embedded within the PCB; a power electronic substrate arranged below the second side of the PCB and coupled via a solder joint to a metal layer on the second side of the PCB; and a dielectric material layer arranged between the second side of the PCB and the power electronic substrate and arranged laterally next to the solder joint, the dielectric material layer coupling the PCB to the power electronic substrate via a fused joint.

### TECHNICAL FIELD

This disclosure relates in general to a power semiconductor assembly comprising an embedded power semiconductor die as well as to a method for fabricating a power semiconductor assembly.

### BACKGROUND

In many power electronics applications, for example in traction inverters, there may be certain requirements which need to be fulfilled by the components of the application. Such requirements may e.g. comprise one or more of a low thermal resistance, a low stray inductance and low development and production costs. Chip embedding may be a technology which can help with implementing these requirements. However, properly electrically insulating an embedded chip from a heatsink may be challenging (for example because there may be unresolved issues concerning the question of how to fabricate a ceramic substrate suitable for embedding or the question of how to properly embed a ceramic substrate in a laminate). Improved power semiconductor assemblies as well as improved methods for fabricating a power semiconductor assembly may help with solving these and other problems.

### SUMMARY

Various aspects pertain to a power semiconductor assembly, comprising: a first power semiconductor die comprising a first side and an opposite second side, a first metal substrate comprising a first side and an opposite second side, wherein the first side comprises a recess in which the first power semiconductor die is arranged such that the second side of the first power semiconductor die faces a bottom side of the recess, a printed circuit board comprising a first side and an opposite second side, wherein the first power semiconductor die and the first metal substrate are embedded within the printed circuit board between the first and second sides of the printed circuit board, a power electronic substrate arranged below the second side of the printed circuit board and coupled via a first solder joint to a metal layer on the second side of the printed circuit board, and a dielectric material layer arranged between the second side of the printed circuit board and the power electronic substrate and arranged laterally next to the first solder joint, the dielectric material layer coupling the printed circuit board to the power electronic substrate via a fused joint.

Various aspects pertain to a method for fabricating a power semiconductor assembly, the method comprising: providing an embedding part, comprising: a first power semiconductor die comprising a first side and an opposite second side, a first metal substrate comprising a first side and an opposite second side, wherein the first side comprises a recess in which the first power semiconductor die is arranged such that the second side of the first power semiconductor die faces a bottom side of the recess, and a printed circuit board comprising a first side and an opposite second side, wherein the first power semiconductor die and the first metal substrate are embedded within the printed circuit board between the first and second sides of the printed circuit board; arranging a power electronic substrate below the second side of the printed circuit board; arranging a dielectric material layer between the second side of the printed circuit board and the power electronic substrate; coupling via a first solder joint the power electronic substrate to a metal layer on the second side of the printed circuit board; and coupling via a fused joint formed using the dielectric material layer the power electronic substrate to the printed circuit board, wherein the dielectric material layer is arranged laterally next to the first solder joint.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIG. 1 shows a schematic sectional view of a power semiconductor assembly comprising a power semiconductor die embedded in a PCB and a power electronic substrate arranged at a bottom side of the PCB.

FIG. 2 shows a schematic sectional view of a further power semiconductor assembly, wherein two power semiconductor dies are embedded in the PCB and are electrically connected to each other, and wherein portions of a metal layer of the power electronic substrate below the two dies are electrically insulated from each other by a dielectric material layer.

FIGS. 3A to 3D show the power semiconductor assembly of FIG. 2 in various stages of fabrication according to an exemplary method for fabricating a power semiconductor assembly.

FIG. 4 shows a further power semiconductor assembly, wherein the dielectric material layer is provided in the form of a molded body.

FIG. 5 shows a further power semiconductor assembly which is configured for double sided cooling.

FIG. 6 is a flow chart of an exemplary method for fabricating a power semiconductor assembly.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

In several examples layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, molding.

An efficient power semiconductor assembly as well as an efficient method for fabricating a power semiconductor assembly may, for example, reduce material consumption, ohmic losses, chemical waste, etc. and may thus enable energy and/or resource savings. Improved power semiconductor assemblies as well as improved methods for fabricating a power semiconductor assembly, as specified in this description, may thus at least indirectly contribute to green technology solutions, i.e. climate-friendly solutions providing a mitigation of energy and/or resource use.

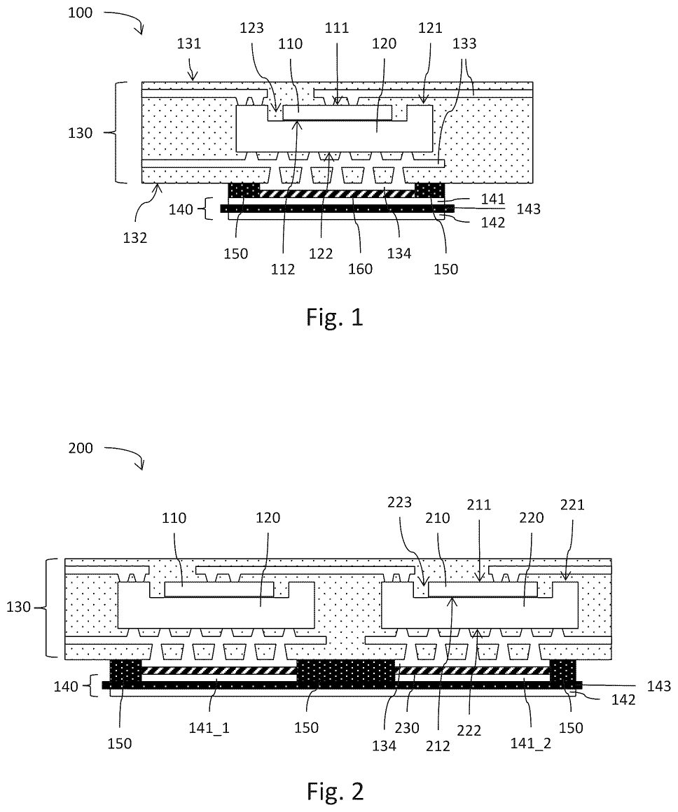

FIG. 1 shows a sectional view of a power semiconductor assembly 100 comprising a first power semiconductor die 110, a first metal substrate 120, a printed circuit board (PCB) 130, a power electronic substrate 140 and a dielectric material layer 150.

The power semiconductor assembly 100 may be configured to operate with (e.g. to switch) a strong electrical current, e.g. a current of 1 A or more, or 10 A or more, or 100 A or more and/or to operate with a high voltage, e.g. a voltage of 500V or more, or 1 kV or more, or 1.2 kV or more, or 2 kV or more.

The power semiconductor assembly 100 may comprise or be part of any suitable electrical circuit, for example a converter circuit, an inverter circuit, a half bridge circuit, a full bridge circuit, etc. The power semiconductor assembly 100 may, for example, be configured for use in automotive applications. The power semiconductor assembly 100 may, for example, be configured for use in a traction inverter.

The first power semiconductor die 110 comprises a first side 111 and an opposite second side 112. The first power semiconductor die 110 may, for example, comprise a first power electrode on the first side 111 and a second power electrode on the second side 112. According to an example, the first power electrode is a source electrode or an emitter electrode and the second power electrode is a drain electrode or a collector electrode. According to another example, it is the other way around. The first power semiconductor die 110 may further comprise a gate electrode which may, for example, be arranged on the first side.

According to an example, the power semiconductor assembly 100 comprises solely the first power semiconductor die 110. According to another example, the power semiconductor assembly comprises a plurality of (power) semiconductor dies. The semiconductor dies may all be the same type of die or different types of dies.

In the case that the power semiconductor assembly 100 comprises a plurality of semiconductor dies, each of the semiconductor dies may be arranged on a separate metal substrate. However, it is also possible that at least some of the semiconductor dies are arranged on a common metal substrate.

The first metal substrate 120 comprises a first side 121 and an opposite second side 122. The first side 121 comprises a recess 123 and the first power semiconductor die 110 is arranged in the recess 123 such that the second side 112 of the first power semiconductor die 110 faces a bottom side of the recess 123.

The first metal substrate 120 may, for example, be a metal block. The first metal substrate 120 may, for example, be a part which was singulated out of a metal sheet, e.g. via punching or cutting or etching or milling. The first metal substrate 120 may comprise or consist of any suitable metal or metal alloy. The first metal substrate 120 may, for example, comprise or consist of Al or Cu.

The first metal substrate 120 may have any suitable dimensions. For example, the first metal substrate 120 may have a length and/or a width (the length and width being measured parallel to the first and second sides 121, 122) in the range of about 5 mm to about 10 cm. The lower limit of this range may also be about 10 mm, or about 15 mm, or about 2 cm, or about 3 cm, or about 4 cm, or about 5 cm and the upper limit may also be about 9 cm, or about 8 cm, or about 7 cm, or about 6 cm. The first metal substrate 120 may, for example, have a thickness (the thickness being measured perpendicular to the first and second sides 121, 122) in the range of about 500 μm to about 10 mm. The lower limit of this range may also be about 800 μm, or about 1 mm, or about 1.27 mm, or about 1.5 mm, or about 2 mm, or about 3 mm, or about 4 mm and the upper limit may also be about 9 mm, or about 8 mm, or about 7 mm, or about 6 mm, or about 5 mm.

The recess 123 may, for example, be fabricated by one or more of punching, milling and etching the first side 121 of the first metal substrate 120. The recess 123 may, for example, have a length and/or a width in the range of about 2 mm to about 5 cm. The lower limit of this range may also be about 3 mm, or about 4 mm, or about 5 mm, or about 6 mm, or about 8 mm, or about 10 mm, or about 15 mm and the upper limit may also be about 4 cm, or about 3 cm, or about 2 cm. The recess 123 may, for example, have a depth in the range of about 50 μm to about 1 mm. The lower limit of this range may also be about 80 μm, or about 100 μm, or about 137 μm, or about 150 μm, or about 200 μm, or about 300 μm and the upper limit may also be about 800 μm, or about 600 μm, or about 400 μm.

According to an example, the first metal substrate 120 is configured to act as a heatspreader for spreading heat generated by the first power semiconductor die 110 during operation. Additionally or alternatively, the first metal substrate 120 may be electrically connected to the first power semiconductor die 110 (in particular, to the second power electrode on the second side 112 of the power semiconductor die 110) and the first metal substrate 120 may be configured to connect the power semiconductor die 110 to other parts of the power semiconductor assembly 100 (e.g. to a redistribution layer). The first power semiconductor die 110 may, for example, be soldered or sintered or glued with conductive glue to the bottom side of the recess 123.

The PCB 130 comprises a first side 131 and an opposite second side 132, wherein the first power semiconductor die 110 and the first metal substrate 120 are embedded within the PCB 130 between the first and second sides 131, 132. The power semiconductor die 110 and the first metal substrate 120 may be embedded in the PCB 130 such that no part of the power semiconductor die 110 and possibly also no part of the first metal substrate 120 are exposed from the PCB 130.

The PCB 130 may comprise any suitable dielectric material, for example a laminate material like FR-4. The PCB 130 may additionally comprise any suitable number of metal layers arranged on and/or within the dielectric material. Such metal layer(s) may, for example, comprise or consist of Al or Cu. Such metal layer(s) may be configured as electrical redistribution layer(s) and/or may be configured for heat dissipation.

In the example shown in FIG. 1, a plurality of embedded redistribution 133 is shown. The layers redistribution layers 133 may be arranged between the first and second sides 131, 132 of the PCB 130. The redistribution layers 133 may, for example, be electrically connected to the first power electrode on the first side 111 of the power semiconductor die 110 and/or to the first metal substrate 120.

The PCB 130 may have any suitable dimensions. For example, the PCB 130 may have a length and/or width (the length and width being measured parallel to the first and second sides 131, 132) in the range of about 1 cm to about 20 cm. The lower limit of this range may also be about 2 cm, or about 4 cm, or about 6 cm, or about 8 cm and the upper limit may also be about 18 cm, or about 16 cm, or about 14 cm, or about 12 cm, or about 10 cm. The PCB 130 may, for example, have a thickness (the thickness being measured between the first and second sides 131, 132) in the range of 2 mm to 5 cm. The lower limit of this range may also be about 4 mm, or about 6 mm, or about 8 mm, or about 1 cm and the upper limit may also be about 4 cm, or about 3 cm, or about 2 cm, or about 1.5 cm.

The power electronic substrate 140 is arranged below the second side 132 of the PCB 130. The power electronic substrate 140 is coupled via a first solder joint 160 to a metal layer 134 on the second side 132 of the PCB 130. According to another example, a sintered joint instead of a solder joint is used.

The power electronic substrate 140 may, for example, comprise a first metal layer 141, a second metal layer 142 and an insulating layer 143 (e.g. a ceramic layer) arranged between the metal layers 141, 142. The power electronic substrate 140 may, for example, be a substrate a direct copper bonded (DCB) substrate, a direct aluminum bonded (DAB) substrate, an active metal brazed (AMB) substrate, or insulated metal substrate (IMS).

The power electronic substrate 140 may, for example, cover the whole second side 132 of the PCB 130 or the power electronic substrate 140 may cover only a portion of the second side 132 (the latter case is shown in FIG. 1). The power electronic substrate 140 may, for example, cover 20% or more, or 30% or more, or 50% or more, or 70% or more, or 90% or more of the second side 132.

The power electronic substrate 140 may be configured to be coupled to a heatsink such that the second metal layer 142 faces the heatsink. The power electronic substrate 140 may be configured to electrically insulate the heatsink from the first power semiconductor die 110 and the first metal substrate 120. This may, for example, be necessary because the first metal substrate 120 may be electrically connected to the metal layer 134 on the second side of the PCB 130 by one or more electrical connectors like vias.

The dielectric material layer 150 is arranged between the second side 132 of the PCB 130 and the power electronic substrate 140. The dielectric material layer 150 is further arranged laterally next to the first solder joint 160. The dielectric material layer 150 couples the PCB 130 to the power electronic substrate 140 via a fused joint.

The fused joint may, for example, be fabricated by heating the dielectric material layer 150 such that the dielectric material layer 150 at least partially liquefies, pressing the at least partially liquefied dielectric material against the second side 132 of the PCB 130 and allowing the at least partially liquefied dielectric material to solidify.

As shown in the example of FIG. 1, the dielectric material layer 150 may be in direct contact with dielectric material of the PCB 130 (e.g. a laminate material like FR-4 or a solder resist). However, according to another example it is also possible that the dielectric material layer 150 is in direct contact with the metal layer 134 of the PCB 130.

The dielectric material of the dielectric material layer 150 may be required to fulfill one or more or all of the following requirements: electrically isolating; reliably adheres to the first metal layer 141 or the dielectric (e.g. ceramic) layer 143 of the power electronic substrate 140 and to the metal layer 134 or the dielectric material of the PCB 130; long-term stability for temperatures up to about 150° C. or even about 175° C.; short-term resilience for temperatures up to about 200° C.

The dielectric material layer 150 may, for example, comprise or consist of a thermoplastic material. The dielectric material layer 150 may, for example, comprise or consist of one or more of glue, a tape, silicone and paste. The glue, silicone or tape may be cured during a soldering process which provides the first solder joint 160.

FIG. 2 shows a further power semiconductor assembly 200 which may be similar or identical to the power semiconductor assembly 100, except for the differences described in the following.

In particular, the power semiconductor assembly 200 may comprise all components described with respect to the power semiconductor assembly 100 and the power semiconductor assembly 200 additionally comprises a second power semiconductor die 210 and a second metal substrate 220.

The second power semiconductor die 210 comprises a first side 211 and an opposite second side 212. The second metal substrate 220 comprises a first side 221 and an opposite second side 222, wherein the first side 221 comprises a recess 223 and wherein the second power semiconductor die 210 is arranged in the recess 223 such that the second side 212 of the second power semiconductor die 210 faces a bottom side of the recess 223. Furthermore, the second power semiconductor die 210 and the second metal substrate 220 are embedded within the printed circuit board 130 laterally next to the first metal substrate 120.

The first and second power semiconductor dies 110, 210 may be electrically connected via one or more redistribution layers 133 of the PCB 130 (and possibly via the second metal substrate 220, compare FIG. 2). The connected semiconductor dies 110, 210 may, for example, provide a half bridge circuit.

The first metal layer 141 of the power electronic substrate 140 comprises a first portion 141_1 arranged vertically below the first metal substrate 120 and a second portion 141_2 arranged vertically below the second metal substrate 220. The second portion 141_2 may be coupled to the metal layer 134 on the second side 132 of the PCB 130 by a second solder joint 230.

A gap between the first portion 141_1 and the second portion 141_2 is filled by the dielectric material layer 150. In this manner, the dielectric material layer 150 may electrically insulate the first and second portions 141_1, 141_2 from each other. A strength of the electrical insulation provided by the dielectric material layer 150 filling the gap may, for example, be 500V or more, or 800V or more, or 1 kV or more, or 1.2 kV or more, or 2 kV or more.

The power electronic substrate 140 and the dielectric material layer 150 may provide a reliable but comparatively cheap way of electrically insulating the second power electrodes arranged on the second sides 112, 212 of the first and second power semiconductor dies 110, 210 from each other as well as from a heatsink. In other words, there is no need to provide an insulating layer between the first sides 121, 221 and second sides 122, 222 of the first and second metal substrates 120, 220 because the required electrical insulation is provided by the power electronic substrate 140 and the dielectric material layer 150, external to the PCB 130.

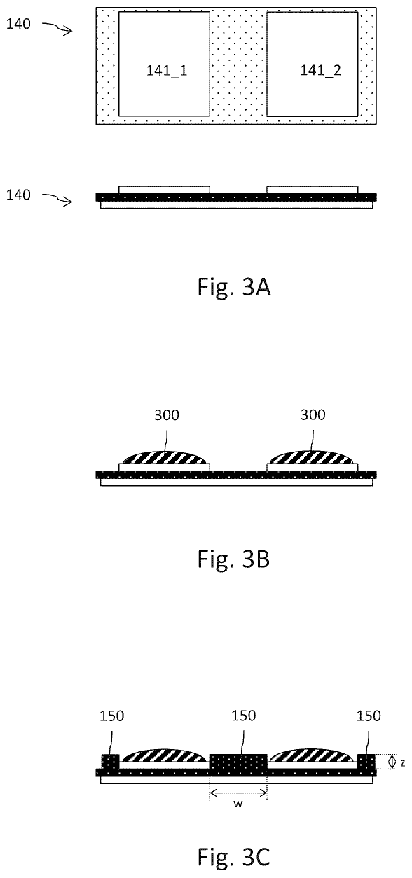

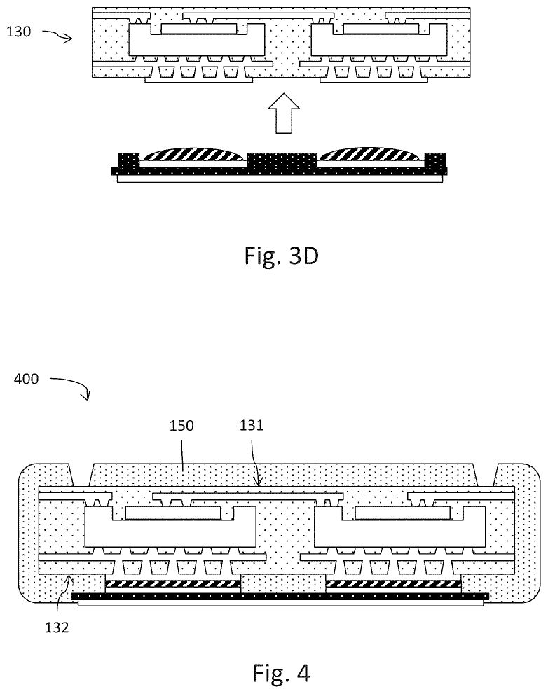

FIGS. 3A to 3D show the power semiconductor assembly 200 in various stages of fabrication according to an exemplary method for fabricating a power semiconductor assembly.

As shown in FIG. 3A, the power electronic substrate 140 is provided. The upper part of FIG. 3A shows a top view and the bottom part shows a sectional view of the power electronic substrate 140. In the example shown in FIG. 3A, the first metal layer 141 of the power electronic substrate 140 comprises two portions 141_1 and 141_2. However, the first metal layer 141 may comprise any suitable number of portions (the number, arrangement and dimensions of these portions may correspond to the number, arrangement and dimensions of metal substrates in the PCB 130).

As shown in FIG. 3B, solder material 300 is deposited on the first metal layer 141 of the power electronic substrate 140. The solder material 300 may, for example, be deposited in liquid form or as a paste.

As shown in FIG. 3C, the dielectric material of the dielectric material layer 150 is deposited on the power electronic substrate 140. For example, the dielectric material may be deposited in the form of a frame configured to surround the first and second portions 141_1, 141_2 of the first metal layer 141. According to another example, the dielectric material is deposited in liquid form.

A width w of the gap between the first and second portions 141_1, 141_2 of the first metal layer 141 may, for example, be in the range of about 0.5 mm to about 5 mm. The lower limit of this range may also be about 1 mm, or about 1.5 mm, or about 2 mm and the upper limit may also be about 4 mm, or about 3 mm. A height z of the dielectric material layer 150 may, for example, be in the range of about 50 μm to about 200 μm. The lower limit of this range may also be about 100 μm and the upper limit may also be about 150 μm.

As shown in FIG. 3D, the PCB 130 comprising the power semiconductor dies 110, 210 and the metal substrates 120, 220 is provided. Heat and possibly also pressure are applied to fabricate the solder joints 160, 230 using the solder material 300 and to fabricate the fused joint using the dielectric material of the dielectric material layer 150, as described further above.

FIG. 4 shows a further power semiconductor assembly 400 which may be similar or identical to the power semiconductor assemblies 100 and 200, except for the differences described in the following.

In particular, in the power semiconductor assembly the dielectric material layer 150 is provided in the form of a molded body. The molded body may, for example, be fabricated using a process like compression molding, injection molding or transfer molding. According to an example, the molded body partially or completely covers the second side 132 of the PCB 130 and the molded body may also partially or completely cover the first side 131 and/or lateral sides connecting the first and second sides 131, 132 of the PCB 130.

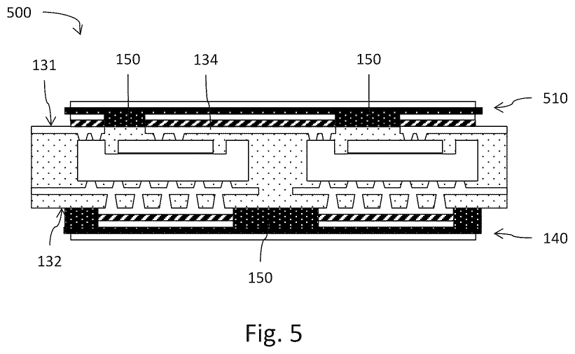

FIG. 5 shows a further power semiconductor assembly 500 which may be similar or identical to the power semiconductor assemblies 100 to 400, except for the differences described in the following.

In particular, the power semiconductor assembly 500 is configured for double sided cooling (DSC), meaning that a first heatsink may be arranged over the first side 131 of the PCB 130 and a second heatsink may be arranged over the second side 132 of the PCB 130. In order to be coupled to both heatsinks, the power semiconductor assembly 500 may comprise the power electronic substrate 140 arranged at the second side 132 and a further power electronic substrate 510 arranged at the first side 131.

The further power electronic substrate 510 may be mechanically coupled to the PCB 130 via a further fused joint fabricated using a further dielectric material layer 150, in a similar manner as described with respect to the power electronic substrate 140. Furthermore, the PCB 130 of the power semiconductor assembly 500 may comprise a further metal layer 134 exposed from the first side 131 of the PCB and the further power electronic substrate 510 may be soldered to this further metal layer 134. The further dielectric material layer 150 may of course also be configured to electrically isolate portions of a metal layer of the further power electronic substrate 510 from each other, as described further above with respect to the dielectric material layer 150.

According to an example, a molding process is used to fabricate the dielectric material layers 150 between the power electronic substrates 140, 510 and the PCB 130, as described with respect to the power semiconductor assembly 400. According to another example, the dielectric material layers 150 are fabricated as described with respect to the power semiconductor assembly 100.

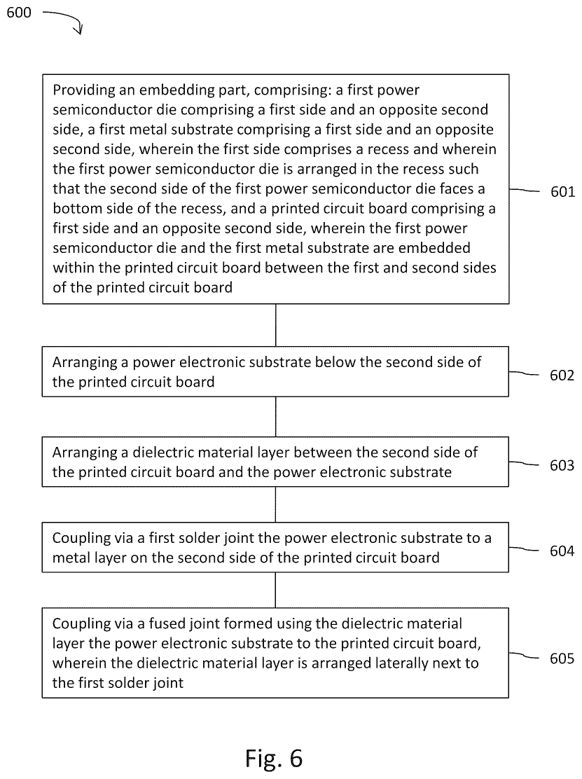

FIG. 6 is a flow chart of a method 600 for fabricating a power semiconductor assembly. The method 600 may, for example, be used to fabricate the power semiconductor assemblies 100 to 500.

The method 600 comprises at 601 a process of providing an embedding part, the embedding part comprising: a first power semiconductor die comprising a first side and an opposite second side, a first metal substrate comprising a first side and an opposite second side, wherein the first side comprises a recess and wherein the first power semiconductor die is arranged in the recess such that the second side of the first power semiconductor die faces a bottom side of the recess, and a printed circuit board comprising a first side and an opposite second side, wherein the first power semiconductor die and the first metal substrate are embedded within the printed circuit board between the first and second sides of the printed circuit board; the method 600 comprises at 602 a process of arranging a power electronic substrate below the second side of the printed circuit board; at 603 a process of arranging a dielectric material layer between the second side of the printed circuit board and the power electronic substrate; at 604 a process of coupling via a first solder joint the power electronic substrate to a metal layer on the second side of the printed circuit board; and at 605 a process of coupling via a fused joint formed using the dielectric material layer the power electronic substrate to the printed circuit board, wherein the dielectric material layer is arranged laterally next to the first solder joint.

In the following, the power semiconductor assembly and the method for fabricating a power semiconductor assembly are further explained using specific examples.

Example 1 is a power semiconductor assembly, comprising: a first power semiconductor die comprising a first side and an opposite second side, a first metal substrate comprising a first side and an opposite second side, wherein the first side comprises a recess in which the first power semiconductor die is arranged such that the second side of the first power semiconductor die faces a bottom side of the recess, a printed circuit board comprising a first side and an opposite second side, wherein the first power semiconductor die and the first metal substrate are embedded within the printed circuit board between the first and second sides of the printed circuit board, a power electronic substrate arranged below the second side of the printed circuit board and coupled via a first solder joint to a metal layer on the second side of the printed circuit board, and a dielectric material layer arranged between the second side of the printed circuit board and the power electronic substrate and arranged laterally next to the first solder joint, the dielectric material layer coupling the printed circuit board to the power electronic substrate via a fused joint.

Example 2 is the power semiconductor assembly of example 1, wherein the power electronic substrate comprises an electrically insulating layer arranged between a first and a second metal layer, wherein the first metal layer faces the printed circuit board.

Example 3 is the power semiconductor assembly of example 2, wherein the second metal layer of the power electronic substrate is configured to be coupled to a heatsink.

Example 4 is the power semiconductor assembly of one of the preceding examples, wherein the power electronic substrate is a direct copper bonded substrate, a direct aluminum bonded substrate, an active metal brazed substrate, an or insulated metal substrate.

Example 5 is the power semiconductor assembly of one of the preceding examples, wherein the first power semiconductor die comprises a first power electrode on the first side and a second power electrode on the second side, and wherein the second power electrode is electrically connected to the first metal substrate.

Example 6 is the power semiconductor assembly of example 5, wherein the printed circuit board comprises one or more embedded redistribution layers arranged between the first and second sides, wherein the one or more redistribution layers are electrically connected to the first power electrode and/or to the first metal substrate.

Example 7 is the power semiconductor assembly of one of the preceding examples, wherein the dielectric material of the dielectric material layer comprises or consists of a thermoplastic material.

Example 8 is the power semiconductor assembly of one of examples 1 to 6, wherein the dielectric material of the dielectric material layer comprises or consists of a mold material.

Example 9 is the power semiconductor assembly of one of the preceding examples, further comprising: a second power semiconductor die comprising a first side and an opposite second side, a second metal substrate comprising a first side and an opposite second side, wherein the first side comprises a recess in which the second power semiconductor die is arranged such that the second side of the second power semiconductor die faces a bottom side of the recess, wherein the second power semiconductor die and the second metal substrate are embedded within the printed circuit board between the first and second sides of the printed circuit board and laterally next to the first metal substrate, wherein a first metal layer of the power electronic substrate comprises a first portion arranged vertically below the first metal substrate and a second portion arranged vertically below the second metal substrate, and wherein the dielectric material layer fills a gap between the first portion and the second portion.

Example 10 is the power semiconductor assembly of example 9, wherein the first portion is coupled to the metal layer on the second side of the printed circuit board by the first solder joint and the second portion is coupled to the metal layer on the second side of the printed circuit board by a second solder joint.

Example 11 is the power semiconductor assembly of one of examples 9 or 10, wherein a width of the gap is in the range of 0.5 mm to 5 mm, in particular in the range of 1 mm to 3 mm, the width being measured parallel to the second side of the printed circuit board.

Example 12 is the power semiconductor assembly of one of examples 9 to 11, wherein the dielectric material layer filling the gap provides an electrical insulation between the first and second portions of the first metal layer of the power electronic substrate of 1.2 kV or more.

Example 13 is the power semiconductor module of one of examples 9 to 12, wherein the first power semiconductor die and the second power semiconductor die are electrically connected to each other via the printed circuit board to form a half bridge circuit.

Example 14 is a method for fabricating a power semiconductor assembly, the method comprising: providing an embedding part, comprising: a first power semiconductor die comprising a first side and an opposite second side, a first metal substrate comprising a first side and an opposite second side, wherein the first side comprises a recess in which the first power semiconductor die is arranged such that the second side of the first power semiconductor die faces a bottom side of the recess, and a printed circuit board comprising a first side and an opposite second side, wherein the first power semiconductor die and the first metal substrate are embedded within the printed circuit board between the first and second sides the printed circuit board; arranging a power electronic substrate below the second side of the printed circuit board; arranging a dielectric material layer between the second side of the printed circuit board and the power electronic substrate; coupling via a first solder joint the power electronic substrate to a metal layer on the second side of the printed circuit board; and coupling via a fused joint formed using the dielectric material layer the power electronic substrate to the printed circuit board, wherein the dielectric material layer is arranged laterally next to the first solder joint.

Example 15 is the method of example 14, wherein arranging the dielectric material layer between the second side of the printed circuit board and the power electronic substrate comprises depositing a thermoplastic material on the power electronic substrate prior to arranging the power electronic substrate below the second side of the printed circuit board.

Example 16 is the method of example 14 or 15, wherein the first solder joint and the fused joint are formed during the same heating process.

Example 17 is an apparatus comprising means for performing the method according to anyone of examples 14 to 16.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power semiconductor assembly, comprising:
a first power semiconductor die comprising a first side and an opposite second side;
a first metal substrate comprising a first side and an opposite second side, wherein the first side comprises a recess in which the first power semiconductor die is arranged such that the second side of the first power semiconductor die faces a bottom side of the recess;
a printed circuit board comprising a first side and an opposite second side, wherein the first power semiconductor die and the first metal substrate are embedded within the printed circuit board between the first and second sides of the printed circuit board;
a power electronic substrate arranged below the second side of the printed circuit board and coupled via a first solder joint to a metal layer on the second side of the printed circuit board; and
a dielectric material layer arranged between the second side of the printed circuit board and the power electronic substrate and arranged laterally next to the first solder joint, the dielectric material layer coupling the printed circuit board to the power electronic substrate via a fused joint.

2. The power semiconductor assembly of claim 1, wherein the power electronic substrate comprises an electrically insulating layer arranged between a first and a second metal layer, and wherein the first metal layer faces the printed circuit board.

3. The power semiconductor assembly of claim 2, wherein the second metal layer of the power electronic substrate is configured to be coupled to a heatsink.

4. The power semiconductor assembly of claim 1, wherein the power electronic substrate is a direct copper bonded substrate, a direct aluminum bonded substrate, an active metal brazed substrate, or an insulated metal substrate.

5. The power semiconductor assembly of claim 1, wherein the first power semiconductor die comprises a first power electrode on the first side and a second power electrode on the second side, and wherein the second power electrode is electrically connected to the first metal substrate.

6. The power semiconductor assembly of claim 5, wherein the printed circuit board comprises one or more embedded redistribution layers arranged between the first and second sides, and wherein the one or more redistribution layers are electrically connected to the first power electrode and/or to the first metal substrate.

7. The power semiconductor assembly of claim 1, wherein a dielectric material of the dielectric material layer comprises or consists of a thermoplastic material.

8. The power semiconductor assembly of claim 1, wherein a dielectric material of the dielectric material layer comprises or consists of a mold material.

9. The power semiconductor assembly of claim 1, further comprising:
a second power semiconductor die comprising a first side and an opposite second side; and
a second metal substrate comprising a first side and an opposite second side, wherein the first side comprises a recess in which the second power semiconductor die is arranged such that the second side of the second power semiconductor die faces a bottom side of the recess,
wherein the second power semiconductor die and the second metal substrate are embedded within the printed circuit board between the first and second sides of the printed circuit board and laterally next to the first metal substrate,
wherein a first metal layer of the power electronic substrate comprises a first portion arranged vertically below the first metal substrate and a second portion arranged vertically below the second metal substrate, and
wherein the dielectric material layer fills a gap between the first portion and the second portion.

10. The power semiconductor assembly of claim 9, wherein the first portion is coupled to the metal layer on the second side of the printed circuit board by the first solder joint and the second portion is coupled to the metal layer on the second side of the printed circuit board by a second solder joint.

11. The power semiconductor assembly of claim 9, wherein a width of the gap is in a range of 0.5 mm to 5 mm, the width being measured parallel to the second side of the printed circuit board.

12. The power semiconductor assembly of claim 9, wherein the dielectric material layer filling the gap provides an electrical insulation between the first and second portions of the first metal layer of the power electronic substrate of 1.2 kV or more.

13. The power semiconductor module of claim 9, wherein the first power semiconductor die and the second power semiconductor die are electrically connected to each other via the printed circuit board to form a half bridge circuit.

14. A method for fabricating a power semiconductor assembly, the method comprising:
providing an embedding part, comprising:
a first power semiconductor die comprising a first side and an opposite second side;
a first metal substrate comprising a first side and an opposite second side, wherein the first side comprises a recess in which the first power semiconductor die is arranged such that the second side of the first power semiconductor die faces a bottom side of the recess; and
a printed circuit board comprising a first side and an opposite second side, wherein the first power semiconductor die and the first metal substrate are embedded within the printed circuit board between the first and second sides of the printed circuit board;
arranging a power electronic substrate below the second side of the printed circuit board;
arranging a dielectric material layer between the second side of the printed circuit board and the power electronic substrate;
coupling, via a first solder joint, the power electronic substrate to a metal layer on the second side of the printed circuit board; and
coupling, via a fused joint formed using the dielectric material layer, the power electronic substrate to the printed circuit board, wherein the dielectric material layer is arranged laterally next to the first solder joint.

15. The method of claim 14, wherein arranging the dielectric material layer between the second side of the printed circuit board and the power electronic substrate comprises depositing a thermoplastic material on the power electronic substrate prior to arranging the power electronic substrate below the second side of the printed circuit board.

16. The method of claim 14, wherein the first solder joint and the fused joint are formed during a same heating process.
